(19) United States
(12) Patent Application Publication
(10) Pub. No.: US 2022/0121391 A1
(43) Pub. Date: Apr. 21, 2022

(54) MANAGEMENT OF OPERATIONS DURING EXCEPTION HANDLING IN MEMORY

(71) Applicant: Western Digital Technologies, Inc., San Jose, CA (US)

(72) Inventors: SANTHOSH KUMAR SIRIPRAGADA, Bengaluru (IN); SRIDHAR PRUDVI RAJ GUNDA, Bengaluru (IN)

(21) Appl. No.: 17/180,656

(22) Filed: Feb. 19, 2021

Related U.S. Application Data
(60) Provisional application No. 63/092,362, filed on Oct. 15, 2020.

(51) Int. Cl. G06F 3/06

(52) U.S. Cl. CPC G06F 3/0655; G06F 3/0604; G06F 3/0679; G06F 3/064

(57) ABSTRACT

Aspects of a storage device including a plurality of dies and a controller are provided which allow for efficient management of operations during exception handling. Each of the plurality of dies may include at least a block of memory. The controller may be configured to determine a first operation for execution in at least a first block of at least a first die of the plurality of dies. The controller may be further configured to execute the first operation in response to a second die of the plurality of dies being in an exception state; however, the at least one first die may be different from the second die. Accordingly, as some operations may be addressed while exception handling is in progress, latency and/or other overhead of a storage device may be improved.

### CROSS-REFERENCE TO RELATED APPLICATIONS

This application claims priority and benefit of U.S. Provisional Application No. 63/092,362, filed on Oct. 15, 2020, entitled “Management of Operations During Exception Handling in Memory,” the entire contents of which are incorporated herein by reference in its entirety.

### FIELD

This disclosure is generally related to electronic devices and more particularly to storage devices.

### BACKGROUND

Storage devices enable users to store and retrieve data. Examples of storage devices include non-volatile memory devices. A non-volatile memory generally retains data after a power cycle. An example of a non-volatile memory is a flash memory, which may include array(s) of NAND cells on one or more dies. Flash memory may be found in solid-state devices (SSDs), Secure Digital (SD) cards, and the like.

A flash storage device may store control information associated with data. For example, a flash storage device may maintain control tables that include a mapping of logical addresses to physical addresses. This control tables are used to track the physical location of logical sectors, or blocks, in the flash memory. The control tables are stored in the non-volatile memory to enable access to the stored data after a power cycle.

A flash storage device may include multiple dies, each of which may include a block of memory. Various operations can be executed with the flash storage device, such as read and write. Such operations may be held in one or more queues, and then each operation may be selected from its respective queue and executed in one or more blocks of one or more dies.

In some instances, execution of one operation may cause an exception to triggered. In response to an exception being triggered, an exception handling (EH) mode may be initiated. During the EH mode, all operations across all dies may be suspended. Therefore, all operations held in the one or more queues may continue to held in their respective queued positions, and potentially more operations may arrive that should also be held in the one or more queues.

Suspension of all operations across all dies during such an EH mode may cause delays and may lead to inefficiencies. Therefore, a need exists for techniques and solutions to improving the management of various operations when an exception has been triggered in memory.

### SUMMARY

The present disclosure describes various aspects of storage devices that each is configured to manage operations while exception handling (EH) is in progress. The various aspects described herein provide for techniques and solutions to improving the management of operations when an exception has been triggered in memory.

One aspect of a storage device is disclosed herein. The storage device includes a plurality of dies, each die including at least a block of memory, and a controller. The controller is configured to determine a first operation for execution in a first block of a first die of the plurality of dies. The controller is further configured to execute the first operation in response to a second die of the plurality of dies being in an exception state, the first die being different from the second die.

Another aspect of a storage device is disclosed herein. The storage device includes a plurality of dies, each die including at least a block of memory, and a controller. The controller is configured to determine that a first die of the plurality of dies is configured in an EH mode. The controller is further configured to select an operation to issue to a second die of the plurality of dies. The controller is further configured to perform the operation in a block of the second die when the first die is determined to be configured in the EH mode.

A further aspect of a storage device is disclosed herein. The storage device includes a plurality of dies, each die including a block of memory, and a controller. The controller is configured to determine that an operation is configurable for execution without exception handling. The controller is further configured to execute the operation in the block of one die of the plurality of dies based on another die of the plurality of dies being in an exception state and based on the determination that the operation is configurable for execution without the exception handling.

It is understood that other aspects of the storage device and method will become readily apparent to those skilled in the art from the following detailed description, wherein various aspects of apparatuses and methods are shown and described by way of illustration. As will be realized, these aspects may be implemented in other and different forms and its several details are capable of modification in various other respects. Accordingly, the drawings and detailed description are to be regarded as illustrative in nature and not as restrictive.

### BRIEF DESCRIPTION OF THE DRAWINGS

Various aspects of the present invention will now be presented in the detailed description by way of example, and not by way of limitation, with reference to the accompanying drawings, wherein:

FIG. 1 is a block diagram illustrating an exemplary embodiment of a storage device in communication with a host device.

FIG. 2 is a conceptual diagram illustrating an example of a logical-to-physical mapping table in a non-volatile memory of the storage device of FIG. 1.

FIG. 3 is a conceptual diagram illustrating an example of queues holding operations scheduled for execution by a command dispatcher while EH is in progress in one of a plurality of dies.

FIG. 4 is a conceptual diagram illustrating an example of a command dispatcher executing some operations in dies in which EH is not in progress while EH is in progress in another die.

FIG. 5 is a flowchart illustrating a method for executing operations in dies in which EH is not in progress while EH is in progress in another die.

FIG. 6 is a flowchart illustrating a method for management of operations during EH, which is performed by the storage device of FIG. 1.

### DETAILED DESCRIPTION

The detailed description set forth below in connection with the appended drawings is intended as a description of various exemplary embodiments of the present invention and is not intended to represent the only embodiments in which the present invention may be practiced. The detailed description includes specific details for the purpose of providing a thorough understanding of the present invention. However, it will be apparent to those skilled in the art that the present invention may be practiced without these specific details. In some instances, well-known structures and components are shown in block diagram form in order to avoid obscuring the concepts of the present invention. Acronyms and other descriptive terminology may be used merely for convenience and clarity and are not intended to limit the scope of the invention.

The words “exemplary” and “example” are used herein to mean serving as an example, instance, or illustration. Any exemplary embodiment described herein as “exemplary” is not necessarily to be construed as preferred or advantageous over other exemplary embodiments. Likewise, the term “exemplary embodiment” of an apparatus, method or article of manufacture does not require that all exemplary embodiments of the invention include the described components, structure, features, functionality, processes, advantages, benefits, or modes of operation.

As used herein, the term “coupled” is used to indicate either a direct connection between two components or, where appropriate, an indirect connection to one another through intervening or intermediate components. In contrast, when a component referred to as being “directly coupled” to another component, there are no intervening elements present.

In the following detailed description, various aspects of a storage device in communication with a host device will be presented. These aspects are well suited for flash storage devices, such as SSDs and SD cards. However, those skilled in the art will realize that these aspects may be extended to all types of storage devices capable of storing data. Accordingly, any reference to a specific apparatus or method is intended only to illustrate the various aspects of the present invention, with the understanding that such aspects may have a wide range of applications without departing from the spirit and scope of the present disclosure.

A storage device of the present disclosure generally includes multiple dies, with each die being a separate section of memory. For example, a storage device may include a NAND flash chip that having multiple dies. Individually, each dies includes a set of planes (e.g., two, four, eight, or other number of planes), and each of the planes is divided into a set of blocks (potentially, one thousand or more block). A word line may be shared across planes of the dies, with each block of a respective plane being divided into a word line.

Such a storage device may be configured to execute multiple different operations, with some of the operations potentially occurring in parallel across some or all of the dies. For example, “read,” “send,” and “program” (e.g., a program operation may be a write or fast write operation) operations may occur in parallel across some or all dies of the storage device. Accordingly, multiple dies of the storage device are interleaved and connected to a multiplexed bus. Illustratively, a program operation of data having a sufficient size will be written in parallel, with the data being written word line-by-word line across the multiple interleaved dies. A similar process occurs for a read operation—that is, the data will be read word line-by-word line from the multiple interleaved dies.

Execution of an operation by a storage device may sometimes result in a failure (or other unsuccessful outcome). For example, a program failure may occur due to a physical defect in the memory (e.g., a short between word lines, a short between a word line and a memory hole that includes the memory cells, or a short between a word line and a channel of the cell), due to degradation of NAND (e.g., as a result of many program/erase cycles (P/E cycles) over time), or due to process variations between the transistors in the memory cells (e.g., differences in oxide thickness, channel length, doping concentration, and other factors). Failures may also occur due to other factors.

A storage device may be configured to trigger exceptions and initiate exception handling (EH) when failures of some operations occur. Specifically, some operations may be considered “basic” operations, such as “program,” “erase,” and “read,” and the failure of any basic operation may result in EH. During EH, one or more operations may occur in order to correct the failure or prevent the failure from reoccurring. For example, EH may involve one or more read, program, erase, and/or decode operations to recover data or prevent data from being programmed in blocks that are marked as “bad” or failed.

In many instances, EH may occur on one die. However, EH may cause all other operations across multiple other dies (e.g., interleaved dies connected to the same multiplexed bus as the one die on which EH occurs) to be suspended. Therefore, all of the multiple other dies would be idle while EH is occurring on the one die. All of the multiple other dies may be held in an idle state in order to prevent another exception from being triggered while EH for one exception occurs on the one die. In particular, the multiple other dies may be held in the idle state because data corruption may result from more than one exception being triggered at a time and/or because EH is expensive with respect to random access memory (RAM) overhead.

In order to improve management of operations during EH, the present disclosure describes various embodiments of a storage device that is configured to execute some operations on one or more dies other than the die(s) performing EH. For example, read operations may be executed in at least one block of one or more dies in which EH is not occurring while EH is occurring in another die. In some embodiments, read operations may be executed in a block of a die in which EH is not occurring because read operations may be “marked” or otherwise configured so that another exception is not triggered if a read operation fails. Instead, the read operation may be configured to be retried (e.g., rescheduled and/or re-queued). In so doing, multiple exceptions resulting in an extended duration of EH may be avoided.

Operations to be executed in blocks of dies may be held in a set of queues. When other dies not subject to EH are in an idle state, and so the operations are suspended, the set of queues may be blocked so that no operations are de-queued for execution in any blocks of any of the other dies (although a set of queues associated with administrative operations may be exempted from being blocked). As aforementioned, the set of queues may be blocked in order to avoid another exception from being triggered, e.g., because multiple exceptions may accumulate, and thus increase the latency of operations received from a host and/or cause operations to timeout. By configuring read operations such that exceptions are not triggered upon failures, the accumulation of multiple exceptions may be avoided.

Potentially, some other operations in addition to read operations may be similarly configured so that exceptions are not triggered upon failures, and therefore, such other operations may also be executed in blocks of dies in which EH is not occurring. If such other operations were to fail, the other operations may be retried (e.g., rescheduled and/or re-queued). However, operations (e.g., including read operations) may be configured to be retried once, which may avoid operations failing multiple times (e.g., due to a corrupted block or other consistent error) and so increasing latency and/or blocking other operations.

Similarly, internal memory operations (e.g., operations associated with a refresh manager and/or other periodic die/plane maintenance operations) may be executed in at least one block of one or more dies in which EH is not occurring while EH is occurring on another die. Such internal memory operations may be executed without any data loss upon failures, and so triggering other exceptions may be avoided.

By executing some operations in blocks of dies in which EH is not occurring, latency in executing operations and responding to host requests may be reduced and/or other inefficiencies in management of operations may be mitigated during EH. Accordingly, the present disclosure provides various techniques and solutions that improve management of operations during EH.

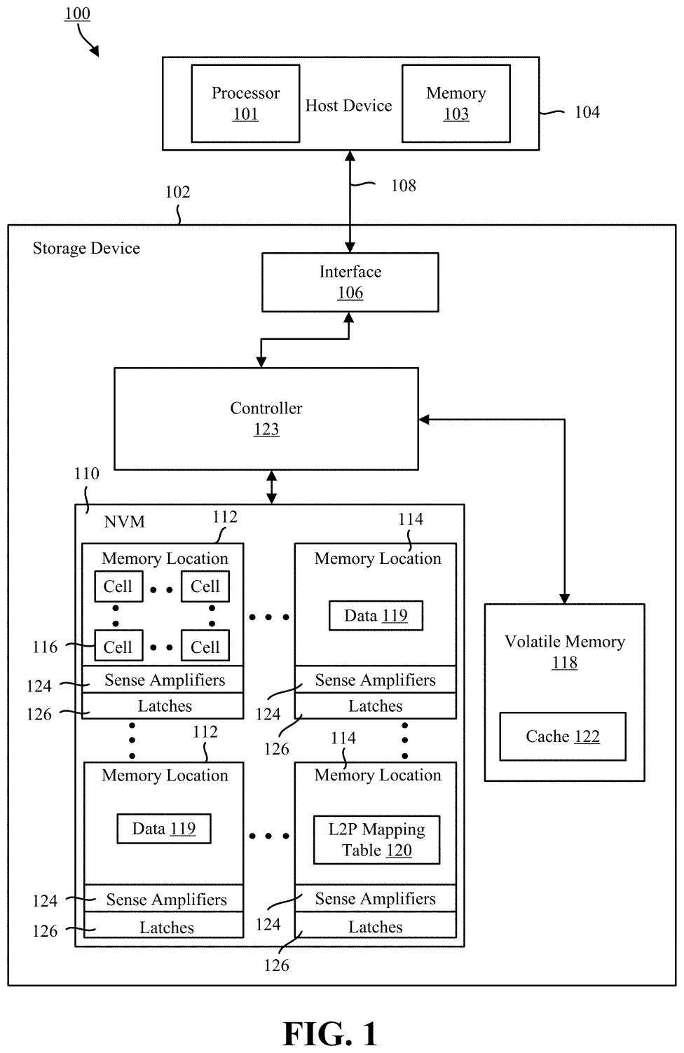

FIG. 1 shows an exemplary block diagram 100 of a storage device 102 which communicates with a host device 104 (also “host”) according to an exemplary embodiment. The host 104 and the storage device 102 may form a system, such as a computer system (e.g., server, desktop, mobile/laptop, tablet, smartphone, etc.). The components of FIG. 1 may or may not be physically co-located. In this regard, the host 104 may be located remotely from storage device 102. Although FIG. 1 illustrates that the host 104 is shown separate from the storage device 102, the host 104 in other embodiments may be integrated into the storage device 102, in whole or in part. Additionally or alternatively, the host 104 may be distributed across multiple remote entities, in its entirety, or with some functionality in the storage device 102.

Those of ordinary skill in the art will appreciate that other exemplary embodiments can include more or less than those elements shown in FIG. 1 and that the disclosed processes can be implemented in other environments. For example, other exemplary embodiments can include a different number of hosts communicating with the storage device 102, or multiple storage devices 102 communicating with the host(s).

The host device 104 may store data to, and/or retrieve data from, the storage device 102. The host device 104 may include any computing device, including, for example, a computer server, a network attached storage (NAS) unit, a desktop computer, a notebook (e.g., laptop) computer, a tablet computer, a mobile computing device such as a smartphone, a television, a camera, a display device, a digital media player, a video gaming console, a video streaming device, or the like. The host device 104 may include at least one processor 101 and a host memory 103. The at least one processor 101 may include any form of hardware capable of processing data and may include a general purpose processing unit (such as a central processing unit (CPU)), dedicated hardware (such as an application specific integrated circuit (ASIC)), digital signal processor (DSP), configurable hardware (such as a field programmable gate array (FPGA)), or any other form of processing unit configured by way of software instructions, firmware, or the like. The host memory 103 may be used by the host device 104 to store data or instructions processed by the host or data received from the storage device 102. In some examples, the host memory 103 may include non-volatile memory, such as magnetic memory devices, optical memory devices, holographic memory devices, flash memory devices (e.g., NAND or NOR), phase-change memory (PCM) devices, resistive RAM (ReRAM) devices, magnetoresistive RAM (MRAM) devices, ferroelectric random-access memory (F-RAM), and any other type of non-volatile memory devices. In other examples, the host memory 103 may include volatile memory, such as RAM, dynamic RAM (DRAM), static RAM (SRAM), and synchronous dynamic RAM (SDRAM (e.g., DDR1, DDR2, DDR3, DDR3L, LPDDR3, DDR4, and the like). The host memory 103 may also include both non-volatile memory and volatile memory, whether integrated together or as discrete units.

The host interface 106 is configured to interface the storage device 102 with the host 104 via a bus/network 108, and may interface using, for example, Ethernet or WiFi, or a bus standard such as Serial Advanced Technology Attachment (SATA), PCI express (PCIe), Small Computer System Interface (SCSI), or Serial Attached SCSI (SAS), among other possible candidates. Additionally or alternatively, the host interface 106 may be wireless, and may interface the storage device 102 with the host 104 using, for example, cellular communication (e.g., 5G NR, 4G LTE, 3G, 2G, GSM/UMTS, CDMA One/CDMA2000, etc.), wireless distribution methods through access points (e.g., IEEE 802.11, WiFi, HiperLAN, etc.), Infra Red (IR), Bluetooth, Zigbee, or other Wireless Wide Area Network (WWAN), Wireless Local Area Network (WLAN), Wireless Personal Area Network (WPAN) technology, or comparable wide area, local area, and personal area technologies.

As shown in the exemplary embodiment of FIG. 1, the storage device 102 includes non-volatile memory (NVM) 110 for non-volatilely storing data received from the host 104. The NVM 110 can include, for example, flash integrated circuits, NAND memory (e.g., single-level cell (SLC) memory, multi-level cell (MLC) memory, triple-level cell (TLC) memory, quad-level cell (QLC) memory, penta-level cell (PLC) memory, or any combination thereof), or NOR memory. The NVM 110 may include a plurality of memory locations 112 which may store system data for operating the storage device 102 or user data received from the host for storage in the storage device 102. For example, the NVM may have a cross-point architecture including a 2-D NAND array of memory locations 112 having n rows and m columns, where m and n are predefined according to the size of the NVM. In the illustrated exemplary embodiment of FIG. 1, each memory location 112 may be a block 114 including multiple cells 116. The cells 116 may be single-level cells, multi-level cells, triple-level cells, quad-level cells, and/or penta-level cells, for example. Other examples of memory locations 112 are possible; for instance, each memory location may be a die containing multiple blocks. Moreover, each memory location may include one or more blocks in a 3-D NAND array. Moreover, the illustrated memory locations 112 may be logical blocks which are mapped to one or more physical blocks.

The storage device 102 also includes a volatile memory 118 that can, for example, include a Dynamic Random Access Memory (DRAM) or a Static Random Access Memory (SRAM). Data stored in volatile memory 118 can include data read from the NVM 110 or data to be written to the NVM 110. In this regard, the volatile memory 118 can include a write buffer or a read buffer for temporarily storing data. While FIG. 1 illustrates the volatile memory 118 as being remote from a controller 123 of the storage device 102, the volatile memory 118 may be integrated into the controller 123.

The memory (e.g., NVM 110) is configured to store data 119 received from the host device 104. The data 119 may be stored in the cells 116 of any of the memory locations 112. As an example, FIG. 1 illustrates data 119 being stored in different memory locations 112, although the data may be stored in the same memory location. In another example, the memory locations 112 may be different dies, and the data may be stored in one or more of the different dies.

Each of the data 119 may be associated with a logical address. For example, the NVM 110 may store a logical-to-physical (L2P) mapping table 120 for the storage device 102 associating each data 119 with a logical address. The L2P mapping table 120 stores the mapping of logical addresses specified for data written from the host 104 to physical addresses in the NVM 110 indicating the location(s) where each of the data is stored. This mapping may be performed by the controller 123 of the storage device. The L2P mapping table may be a table or other data structure which includes an identifier such as a logical block address (LBA) associated with each memory location 112 in the NVM where data is stored. While FIG. 1 illustrates a single L2P mapping table 120 stored in one of the memory locations 112 of NVM to avoid unduly obscuring the concepts of FIG. 1, the L2P mapping table 120 in fact may include multiple tables stored in one or more memory locations of NVM.

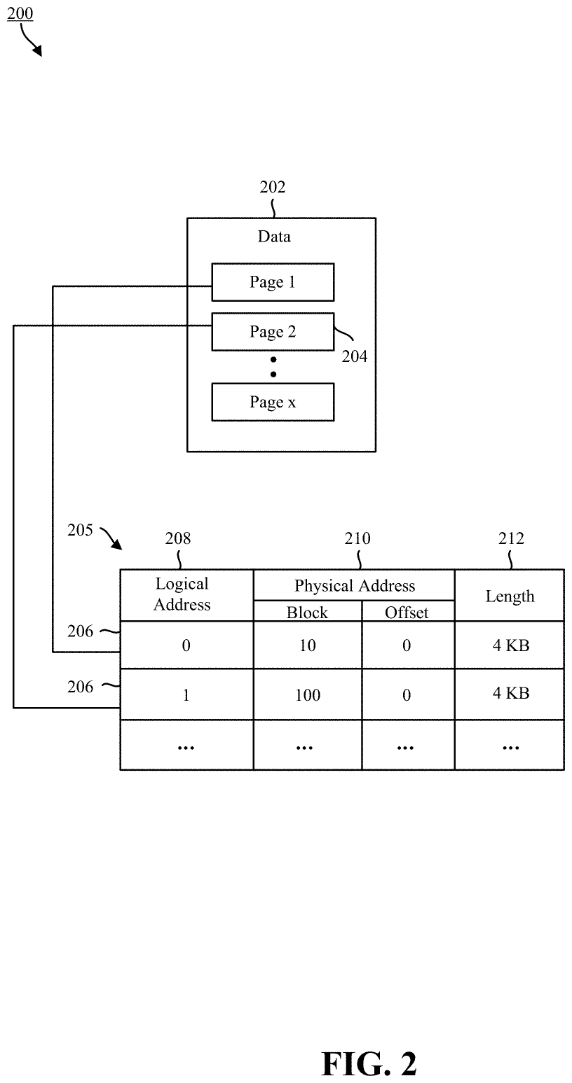

FIG. 2 is a conceptual diagram 200 of an example of an L2P mapping table 205 illustrating the mapping of data 202 received from a host device to logical addresses and physical addresses in the NVM 110 of FIG. 1. The data 202 may correspond to the data 119 in FIG. 1, while the L2P mapping table 205 may correspond to the L2P mapping table 120 in FIG. 1. In one exemplary embodiment, the data 202 may be stored in one or more pages 204, e.g., pages 1 to x, where x is the total number of pages of data being written to the NVM 110. Each page 204 may be associated with one or more entries 206 of the L2P mapping table 205 identifying a logical block address (LBA) 208, a physical address 210 associated with the data written to the NVM, and a length 212 of the data. LBA 208 may be a logical address specified in a write command for the data received from the host device. Physical address 210 may indicate the block and the offset at which the data associated with LBA 208 is physically written. Length 212 may indicate a size of the written data, e.g., 4 kilobytes (KB) or some other size.

Referring back to FIG. 1, the volatile memory 118 also stores a cache 122 for the storage device 102. The cache 122 includes entries showing the mapping of logical addresses specified for data requested by the host 104 to physical addresses in NVM 110 indicating the location(s) where the data is stored. This mapping may be performed by the controller 123. When the controller 123 receives a read command or a write command for data 119, the controller checks the cache 122 for the logical-to-physical mapping of each data. If a mapping is not present (e.g., it is the first request for the data), the controller accesses the L2P mapping table 120 and stores the mapping in the cache 122. When the controller 123 executes the read command or write command, the controller accesses the mapping from the cache and reads the data from or writes the data to the NVM 110 at the specified physical address. The cache may be stored in the form of a table or other data structure which includes a logical address associated with each memory location 112 in NVM where data is being read.

The NVM 110 includes sense amplifiers 124 and data latches 126 connected to each memory location 112. For example, the memory location 112 may be a block including cells 116 on multiple bit lines, and the NVM 110 may include a sense amplifier 124 on each bit line. Moreover, one or more data latches 126 may be connected to the bit lines and/or sense amplifiers. The data latches may be, for example, shift registers. When data is read from the cells 116 of the memory location 112, the sense amplifiers 124 sense the data by amplifying the voltages on the bit lines to a logic level (e.g., readable as a ‘0’ or a ‘1’), and the sensed data is stored in the data latches 126. The data is then transferred from the data latches 126 to the controller 123, after which the data is stored in the volatile memory 118 until it is transferred to the host device 104. When data is written to the cells 116 of the memory location 112, the controller 123 stores the programmed data in the data latches 126, and the data is subsequently transferred from the data latches 126 to the cells 116.

The storage device 102 includes a controller 123 which includes circuitry such as one or more processors for executing instructions and can include a microcontroller, a Digital Signal Processor (DSP), an Application-Specific Integrated Circuit (ASIC), a Field Programmable Gate Array (FPGA), hard-wired logic, analog circuitry and/or a combination thereof.

The controller 123 is configured to receive data transferred from one or more of the cells 116 of the various memory locations 112 in response to a read command. For example, the controller 123 may read the data 119 by activating the sense amplifiers 124 to sense the data from cells 116 into data latches 126, and the controller 123 may receive the data from the data latches 126. The controller 123 is also configured to program data into one or more of the cells 116 in response to a write command. For example, the controller 123 may write the data 119 by sending data to the data latches 126 to be programmed into the cells 116. The controller 123 is further configured to access the L2P mapping table 120 in the NVM 110 when reading or writing data to the cells 116. For example, the controller 123 may receive logical-to-physical address mappings from the NVM 110 in response to read or write commands from the host device 104, identify the physical addresses mapped to the logical addresses identified in the commands (e.g., translate the logical addresses into physical addresses), and access or store data in the cells 116 located at the mapped physical addresses.

The controller 123 and its components may be implemented with embedded software that performs the various functions of the controller described throughout this disclosure. Additionally or alternatively, software for implementing each of the aforementioned functions and components may be stored in the NVM 110 or in a memory external to the storage device 102 or host device 104, and may be accessed by the controller 123 for execution by the one or more processors of the controller 123. Additionally or alternatively, the functions and/or components of the controller may be implemented with hardware and/or firmware in the controller 123, or may be implemented using a combination of the aforementioned hardware, firmware, and/or software.

In operation, the host device 104 stores data in the storage device 102 by sending a write command to the storage device 102 specifying one or more logical addresses (e.g., LBAs) as well as a length of the data to be written. The interface element 106 receives the write command, and the controller allocates a memory location 112 in the NVM 110 of storage device 102 for storing the data. The controller 123 stores the L2P mapping in the NVM (and the cache 122) to map a logical address associated with the data to the physical address of the memory location 112 allocated for the data. The controller also stores the length of the L2P mapped data. The controller 123 then stores the data in the memory location 112 by sending it to one or more data latches 126 connected to the allocated memory location, from which the data is programmed to the cells 116.

The host 104 may retrieve data from the storage device 102 by sending a read command specifying one or more logical addresses associated with the data to be retrieved from the storage device 102, as well as a length of the data to be read. The interface 106 receives the read command, and the controller 123 accesses the L2P mapping in the cache 122 or otherwise the NVM to translate the logical addresses specified in the read command to the physical addresses indicating the location of the data. The controller 123 then reads the requested data from the memory location 112 specified by the physical addresses by sensing the data using the sense amplifiers 124 and storing them in data latches 126 until the read data is returned to the host 104 via the host interface 106.

The abovementioned write and read commands may be two examples of operations that the controller 123 may be configure to execute in the memory locations 112 (e.g., dies). Illustratively, the controller 123 may be configured to execute read, program (e.g., write or fast write), erase, decode, encode, refresh, and/or one or more other operations. A subset of these operations may be regarded as “basic” operations, and may include program, erase, and read operations.

While any operation may fail to be successfully executed, failure of any one of the basic operations may trigger an exception which initiates EH in at least one of the memory locations 112 at which the operation failed. EH may be internally handled by NVM 110 (e.g., by a processor connected to NVM 110) in order to prevent loss or corruption of data. For example, EH may include execution of one or more read, write, erase, and/or decode operations in order to recover data and/or avoid a “bad” one of the cells 116 in one of the memory locations 112. For example, when EH is in progress in one of the memory locations 112, at least one of relocation of data stored in the memory location (e.g., from cell-to-cell, from block-to-block, etc.), a low-density parity-check (LDPC) associated with data, an XOR parity check associated with data, or another error correction code (ECC) operation associated with data is performed. Accordingly, EH may involve one or more buffers of volatile memory 118 so that the associated operation(s) may be performed.

In some embodiments, the failure of a basic operation will trigger an exception that causes EH to occur at the level of the memory locations 112. In other words, failure of an operation executed in one of the cells 116 will cause EH to occur in the one of memory locations 112 that includes the cell in which the operation failed. Consequently, other operations that involve any of the cells 116 in the one of the memory locations 112 having the cell in which the operation failed may be blocked while EH is in progress (e.g., as the operations for EH may be prioritized to prevent data loss or corruption).

However, holding all the memory locations 112 in an idle state while EH is in progress in one memory location may be inefficient and requests from the host 104 may experience increased latency while operations queued to respond to such requests are blocked while all the memory locations 112 are held in the idle state. Therefore, the controller 123 may be configured to execute some operations in cells of memory locations in which EH is not in progress, which may improve performance of the storage device 102, particularly during EH.

Thus, in some embodiments, the controller 123 may be configured to determine a first operation for execution in a first one of the cells 116 of a first one of the memory locations 112. The controller 123 may be further configured to execute the first operation in response to a second one of the memory locations 112 being in an exception or EH state (the first one of the memory locations 112 being different from the second one). For example, the first operation may be one of a read operation, an operation that is internal to the NVM 110, or another operation that is configured to be rescheduled (e.g., re-queued) without generating an exception if execution of the other operation fails.

To that end, the controller 123 may be further configured to determine that the first operation is configured to be rescheduled without EH is execution of the first operation fails, e.g., such that the controller 123 determines the first operation for execution based on the determination that the first operation is configured to be rescheduled without EH is execution of the first operation fails. For example, the controller 123 may determine the first operation for execution, and the controller 123 may store information (e.g., metadata) “marking” and/or configuring prevention of exception triggering or generating (or prevention of EH) if execution of the first operation fails. Thus, the controller 123 may prevent multiple exceptions from being triggered, which may extend the duration of EH in the NVM 110.

Accordingly, the controller 123 may be further configured to determine the execution of the first operation failed, and in response to such a determination that the execution of the first operation failed, the controller 123 may refrain from generating or triggering an exception. Rather, the controller 123 may reschedule the first operation for another execution. For example, the controller 123 may add the first operation to the queue from which the first operation was selected, such as by re-queuing the first operation in its most recent position in the queue or by adding the first operation to another queue different from the one from which the first operation was selected.

However, in some embodiments, an operation that fails on execution without triggering an exception may be rescheduled once, e.g., as opposed to rescheduling an operation multiple times after multiple failures. In some further embodiments, if the operation fails on execution after being rescheduled, then another exception may be triggered, even while EH is in progress on another one of the memory locations 112.

For example, if execution of an operation fails on a first one of the memory locations 112 after being rescheduled while EH is in progress on a second one of the memory locations 112, then the operation may be added to an EH queue. When EH is completed on the second memory location, the NVM 110 (and potentially the controller 123, as well) may remain in an EH mode while the operation is fetched from the EH queue and EH occurs in the first memory location. While holding the NVM 110 (and potentially the controller 123, as well) in the EH mode to handle multiple exceptions (e.g., fetched from the EH queue) may extend the duration of the EH mode, doing so may be less expensive in terms of time and/or computational resource overhead than transitioning out of the EH mode into a normal mode (e.g., in which conventional fetching of operations from queues resumes) and then back into the EH mode for each operation fetched from the EH queue.

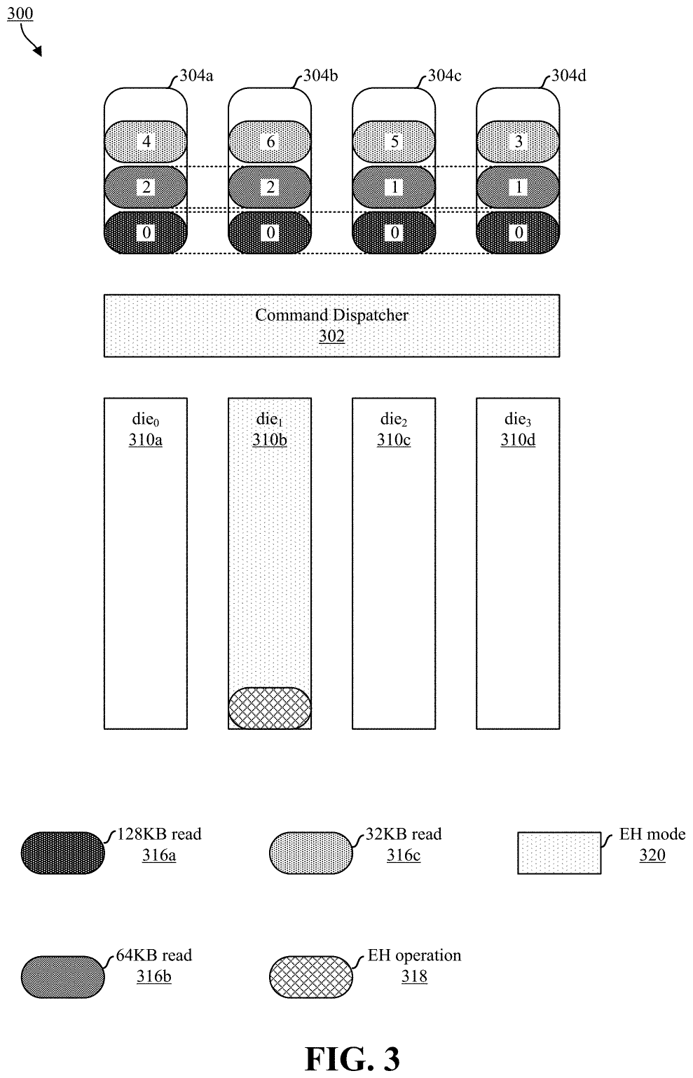

FIG. 3 is a conceptual diagram 300 illustrating an example of queues holding operations scheduled for execution by a command dispatcher while EH is in progress in one of a plurality of dies. In the context of FIG. 1, for example, the command dispatcher 302 may be implemented as the controller 123, the dies 310a-d may be implemented as memory locations 112, and/or the queues 304a-d may be stored in volatile memory 118 or elsewhere (e.g., the NVM 110).

As shown in FIG. 3, a storage device may include multiple dies 310a-d, each of which may be a separate section of memory. In some embodiments, the dies 310a-d may be interleaved and/or connected to a multiplexed bus. Thus, a word line may be shared across the dies 310a-d. For example, each of the dies 310a-d may provide 32 KB of the word line, which may be across two or more blocks of two or more planes. In other examples, each of the dies 310a-d may be of a different size than 32 KB.

As the dies 310a-d may be interleaved, operations may occur in parallel across the dies. For example, a read operation of data having a size of 128 KB will be parallelly executed in blocks of memory in the dies 310a-d, e.g., with the 128 KB of data being read from a word line across multiple blocks of the multiple interleaved dies.

The queues 304a-d may each hold a set of operations scheduled for execution in a block of one of the dies 310a-d. By way of illustration and not limitation, the queues 304a-d may include one or more of an internal high-priority queue, a normal priority queue, a relocation queue, an infra queue, and/or another queue. Other queues may be similarly configured, and may be accessible by the command dispatcher 302, such as an administrative (or admin) queue and an exception (or EH) queue.

In the illustrated example, each of the operations 316a-c held in the queues may be a read operation (or simply “read”). For example, the operations may include 32 KB reads 316a, 64 KB reads 316b, and 128 KB reads 316c (although other sizes are possible without departing from the scope of the present disclosure). In some other examples, one or more of the operations may be internal memory operations and/or another operation that is configurable for execution without EH.

The command dispatcher 302 may be configured to select (e.g., fetch or determine) operations from the queues 304a-d and issue selected operations for execution in blocks of memory of the dies 310a-d. Accordingly, a selected operation issued for execution may be performed in one or more blocks of memory of one or more dies. When the command dispatcher 302 is able to select operations from queues and execute such operations in blocks of memory of the dies without triggering any exceptions (e.g., exceptions that initiate EH operations), the command dispatcher 302 may be operating in (or may be configured in) a “normal” mode or state. Correspondingly, when operations are successfully executed in blocks of memory of the dies 310a-d without triggering any exceptions (e.g., exceptions that initiate EH operations), each of the dies 310a-d may be operating in (or may be configured in) a “normal” mode or state.

Potentially, however, execution of an operation may fail. For example, execution of an operation may fail due to an immature die, physical defects in a die, degradation of a die (e.g., as a result of many P/E cycles over time), process variations between the transistors in the memory cells, or another factor. When some operations fail, an exception may be triggered that initiates EH in the die in which the operation failed to successfully execute. For example, some basic operations, e.g., including at least erase, program, and read, may trigger an exception causing EH to be initiated in response to an execution failure.

By way of illustration and not limitation, the command dispatcher 302 may perform an operation (e.g., a basic operation, such as read, program, or erase) in a block of memory of die₁ 310b. However, performance of the operation in the block of memory of die₁ 310b may fail, thereby triggering an exception causing EH to be initiated.

When EH is initiated, the command dispatcher 302 may transition to an EH mode 320. The EH mode 320 may be different from the abovementioned normal mode in that EH may be prioritized. For example, one or more operations for EH may be placed in an exception (or EH) queue, and the command dispatcher 302 may execute the one or more operations for EH by fetching those one or more operations from the exception queue.

Illustratively, the command dispatcher 302 may execute the EH operation 318 in a block of memory of die₁ 310b, at which the exception was triggered. The EH operation 318 may involve one or more operations, such as read, write, erase, and/or decode, e.g., in order to recover and/or relocate data in the block of memory of die₁ 310b. Thus, die₁ 310b may be placed in (e.g., may transition to) the EH mode 320.

While die₁ 310b is in the EH mode 320, the command dispatcher 302 may refrain from issuing any other operations for execution in a block of die₁ 310b except those operations fetched from the exception queue, such as EH operation 318 (potentially, one or more other queues may also be exempted, e.g., in some embodiments, the command dispatcher 302 may fetch operations from an administrative queue). While die₁ 310b is in the EH mode 320, the remaining dies in which the operation did not fail and are not in the EH mode 320 may be idle.

Rather than holding the other dies not in the EH mode 320 idle, the command dispatcher 302 may be configured to execute some operations in blocks of memory of the other dies. In so doing, latency in responding to host requests (e.g., read, write, erase, and/or other requests) may be reduced. For example, multiple read operations 316a-c may be held in the queues 304a-d awaiting execution in the dies 310a-d while the command dispatcher 302 and die₁ 310b are in the EH mode 320.

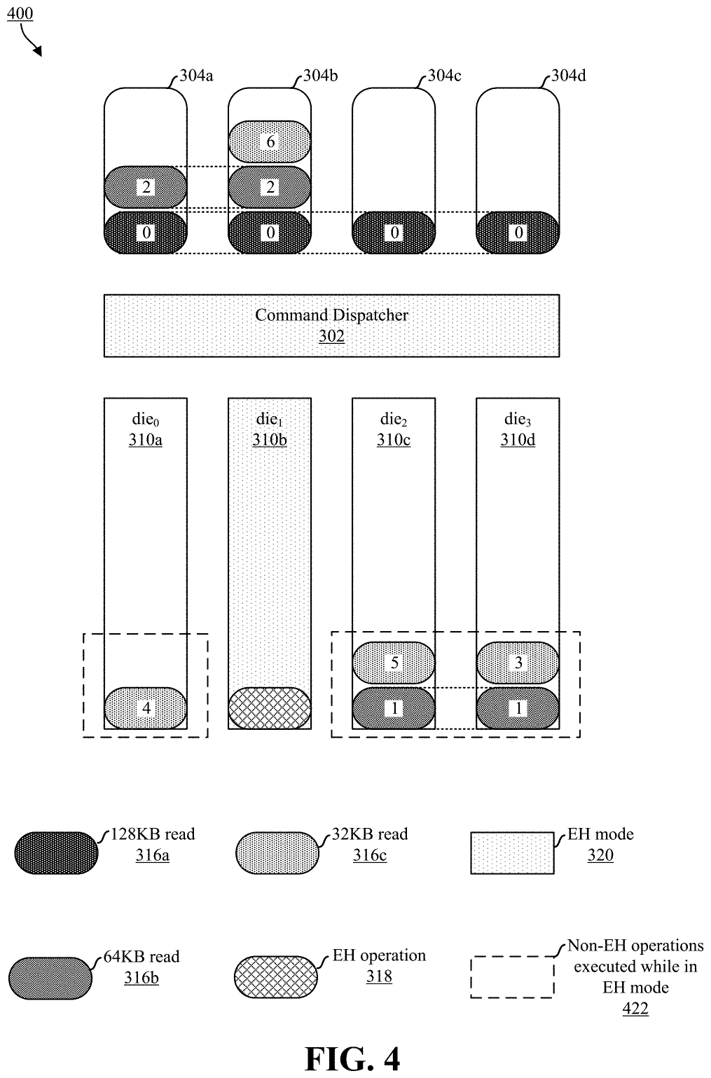

FIG. 4 is a conceptual diagram 400 illustrating an example of a command dispatcher executing some operations in dies in which EH is not in progress while EH is in progress in another die. As shown in FIG. 4, the command dispatcher 302 may be configured to fetch some operations from some queues and execute those operations in dies not in the EH mode 320.

According to various embodiments, the command dispatcher 302 may be configured to fetch some operations that are not to be executed in (e.g., do not correspond to) die₁ 310b in the EH mode 320. For example, the command dispatcher 302 may be configured to fetch read operations, internal memory operations, and other operations that do not trigger exceptions upon failures, and execute such operations in blocks of the dies not in the EH mode 320 while the command dispatcher 302 (and die₁ 310b) is in the EH mode 320. Thus, the command dispatcher 302 may be configured to determine an operation that can be executed in die₀ 310a, die₂ 310c, and die₃ 310d, which are not in the EH mode 320.

Illustratively, the queues 304a-d may include read₀, which may be a 128 KB read 316a that is scheduled to be executed next (e.g., read₀ may have been pushed onto the queues 304a-d before any of the other operations, if the queues are configured as first-in first-out). Accordingly, the command dispatcher 302 may select the read₀ from the queues 304a-d. As described above, the dies 310a-d may be interleaved and connected to a multiplexed bus, and therefore, read₀ may involve all of the dies 310a-d in order to be executed in parallel across each 32 KB of the word line provided by a respective one of the dies 310a-d.

In so doing, however, the command dispatcher 302 may determine that read₀ includes a block of memory of die₁ 310b, which is in the EH mode 320. In response to determining that read₀ includes a block of memory of die₁ 310b in the EH mode 320, the command dispatcher 302 may determine to refrain from executing read₀—e.g., the command dispatcher 302 may hold read₀ in its scheduled position in the queues 304a-d, and may skip read₀.

When the command dispatcher 302 determines to refrain from executing read₀, the command dispatcher 302 may subsequently select read₁ from two queues 310c-d, which may be a 64 KB read 316b that is scheduled to be executed next after read₀. In some embodiments, the command dispatcher 302 may determine that read₁ is able to be rescheduled without EH if execution of read₁ fails—e.g., the command dispatcher 302 may determine that read₁ is configured or is configurable to be rescheduled without EH in response to a failure of read₁ to be successfully executed.

In some embodiments, the command dispatcher 302 may configure read₁ to be rescheduled without EH upon execution failure. For example, the command dispatcher 302 may store (or may associate read₁ with) metadata or other information indicating that an exception is not to be triggered upon execution failure. Additionally or alternatively, the command dispatcher 302 may store metadata or other information indicating that an exception is not to be triggered upon execution failure in response to a determination that read₁ is able to be configured such that such an exception is not triggered upon execution failure.

In addition to determining to execute read₁ when in the EH mode 320 based on the blocks in which read₁ is to be executed being on dies 310c-d that are not in the EH mode 320, the command dispatcher 302 may select read₁ based on the determination (or configuration) of read₁ to be rescheduled without triggering an exception upon execution failure. In some embodiments, however, if read₁ were not configured to be rescheduled without triggering an exception upon execution failure, the command dispatcher 302 may responsively select a different operation (e.g., a later scheduled operation, an operation held in a later position in the queues 304a-d) for execution in one or more of the dies not in the EH mode 320. For example, a write operation may not be configurable to be rescheduled without EH because a failed write operation may involve relocation and/or correction of data in order to avoid corruption or loss of the data.

As read₁ may be executed on dies 310c-d not in EH mode 320, and further, may be associated with metadata or other information indicating associated EH is to be suppressed upon execution failure, the command dispatcher 302 may execute read₁ in blocks of memory of the dies 310c-d in which the data requested by read₁ is located. The command dispatcher 302 may execute read₁ even while EH is occurring on die₁ 310b, which may include the command dispatcher 302 operating in the EH mode.

In some embodiments, read₁ may fail to be successfully executed; however, the command dispatcher 302 may prevent an exception from being triggered upon execution failure, the command dispatcher 302 may refrain from generating an exception in response to determining that read₁ failed and may reschedule read₁ for another execution. For example, the command dispatcher 302 may replace read₁ in its most-recent position in the queues 304c-d or the command dispatcher 302 may add read₁ to another queue from which the command dispatcher 302 may fetch read₁ before fetching other read operations from the queues 304a-d. Accordingly, the command dispatcher 302 may re-execute read₁ in blocks of memory of the dies 310c-d corresponding to the data requested by read₁.

Subsequently, the command dispatcher 302 may fetch the next operation from the queues 304a-d. As illustrated, the next operation may be another 64 KB read 316b, read₂. However, the command dispatcher 302 may determine that read₂ is queued for execution in a set of dies that includes die₁ 310b in the EH mode 320. Thus, even though read₂ may be partially executed in die₀ 310a, which is not in the EH mode 320, the command dispatcher 302 may refrain from executing read₂ because completion of read₂ involves execution in die₁ 310b while it is in the EH mode 320.

Instead, the command dispatcher 302 may skip read₂ and continue on to fetching read₃, even though read₂ is in the queues 304a-d at an earlier position than read₃. As read₃ may be a 32 KB read 316c that does not correspond to die₁ 310b in the EH mode 320 (and read₃ may be rescheduled without triggering an exception upon execution failure), the command dispatcher 302 may execute read₄ in the block(s) of the corresponding die₃ 310d.

Similarly to read₃, the command dispatcher 302 may execute the next two 32 KB reads 316c, read₄ and read₅, in the blocks of the corresponding die₀ 310a and die₂ 310c, respectively. However, the subsequent 32 KB read 316c, read₆, may correspond die₁ 310b held in EH mode 320, and therefore, the command dispatcher 302 may refrain from performing read₆.

Thus, even though not all queued operations may be performed while the command dispatcher 302 is configured with die₁ 310b in the EH mode 320, a set of non-EH operations 422 may nonetheless be executed. Accordingly, latency in performance of some operations may be decreased while EH is in progress in one of the dies 310a-d. Such a decrease in latency may improve overall performance of a storage device, e.g., by reducing overhead and/or reducing the time commensurate with responding to host requests.

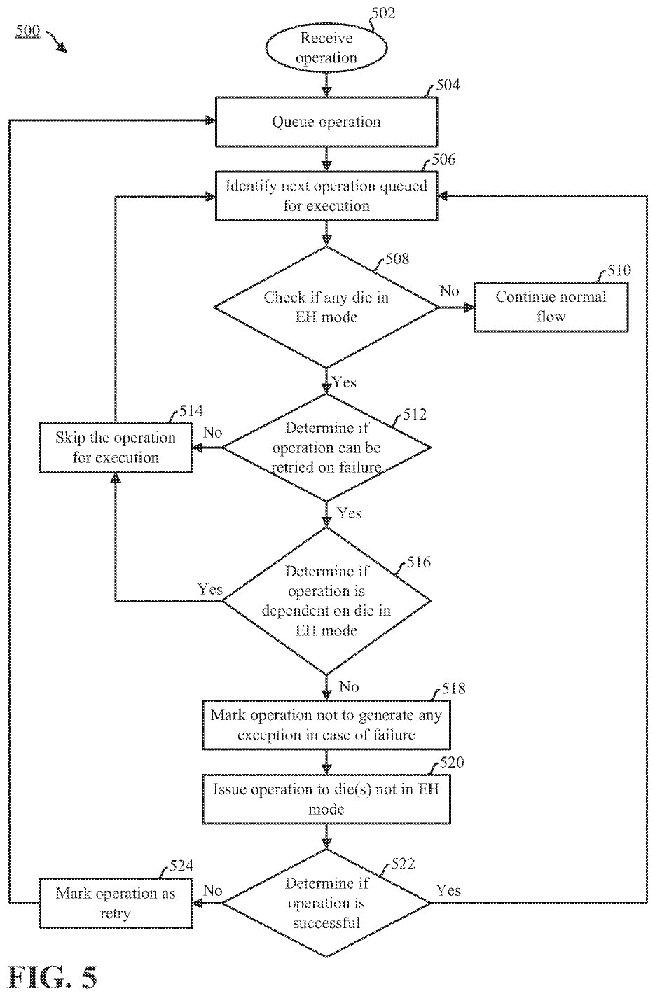

FIG. 5 is a flowchart 500 illustrating a method for executing operations in dies in which EH is not in progress while EH is in progress in another die. For example, the method may be performed in a storage device, such as the storage device 102 illustrated in FIG. 1. Each of the operations in the method can be controlled using a controller, a command dispatcher, or another processor as described below (e.g., the controller 123, the command dispatcher 302), or by some other suitable means.

As represented by block 502, the controller may receive an operation, which may be a request from a host device (e.g., the host 104) or may be another operation (e.g., an internal memory operation). For example, the received operation may be a newly generated operation or an operation commensurate with responding to a newly received request.

As represented by block 504, the controller may add the operation to a queue. In so doing, the controller may schedule the operation for execution in one or more blocks of memory of one or more dies with which the controller is configured to interface.

As represented by block 506, the controller may identify the next operation queued for execution. For example, the controller may determine one of a plurality of queues from which a next operation should be fetched (e.g., a queue having a highest priority in the current operational flow), and next, the controller may fetch the next operation from the determined one of the plurality of queues (e.g., the next operation may be the earliest operation added to the determined queue in a first-in first-out configuration).

As represented by block 508, the controller may check whether any die is in an EH mode. For example, the controller may determine that the next operation is fetched from an exception queue for execution in a die that is in an EH mode, and therefore, the controller may determine that the die is in the EH mode. However, if no operations are scheduled in the exception queue, then no dies may be in the EH mode.

If the controller determines that no dies are in the EH mode, then as represented by block 510, the controller may continue normal flow. In the normal flow, the controller may continue to fetch operations from queues and execute the fetched operations in one or more blocks of one or more interleaved dies.

If the controller determines that a die is in the EH mode, then as represented by block 512, the controller may determine if the next operation can be retried (e.g., rescheduled) on failure to successfully execute. For example, the controller may determine that the next operation can be retried upon execution failure if such execution failure would not result in loss or corruption of any data. Conversely, the controller may determine that the next operation cannot be retried upon execution failure if such execution failure would (or potentially could) result in loss or corruption of any data.

If the controller determines that the next operation cannot be retried upon execution failure, then as represented by block 514, the controller may skip the next operation for execution. Thus, returning to block 506, the controller may identify another next operation for execution.

If the controller determines that the next operation can be retried upon execution failure, then as represented by block 516, the controller may determine if the next operation is dependent on the die in the EH mode. In other words, the controller may determine if at least a portion of the next operation is scheduled for execution in a block of memory of the die in the EH mode.

If the controller determines that the next operation is dependent upon the die in the EH mode, then returning to block 514, the controller may skip the next operation for execution. Thus, returning to block 506, the controller may identify another next operation for execution.

If the controller determines that the next operation is not dependent upon the die in the EH mode, then as represented by block 518, the controller may mark the next operation not to generate any exceptions in case the operation fails to successfully execute.

As represented by block 520, the controller may then issue the next operation to one or more dies that are not in the EH mode. For example, the controller may execute the next operation in block(s) of memory of the die(s) upon which the next operation is dependent.

As represented by block 522, the controller may determine if the operation successfully executed in the block(s) of memory of the die(s) upon which the next operation is dependent. For example, if the next operation is a read operation, then the controller may determine if the correct data was returned in response to execution of the next operation in the block(s) of memory of the die(s) upon which the next operation is dependent.

If the controller determines that the next operation successfully executed, returning to block 506, the controller may identify another next operation for execution.

If the controller determines that the next operation successfully executed, then as represented by block 524, the controller may mark the next operation as a retry. Then returning to block 504, the controller may queue (or reschedule) the next operation, e.g., for immediate or later execution.

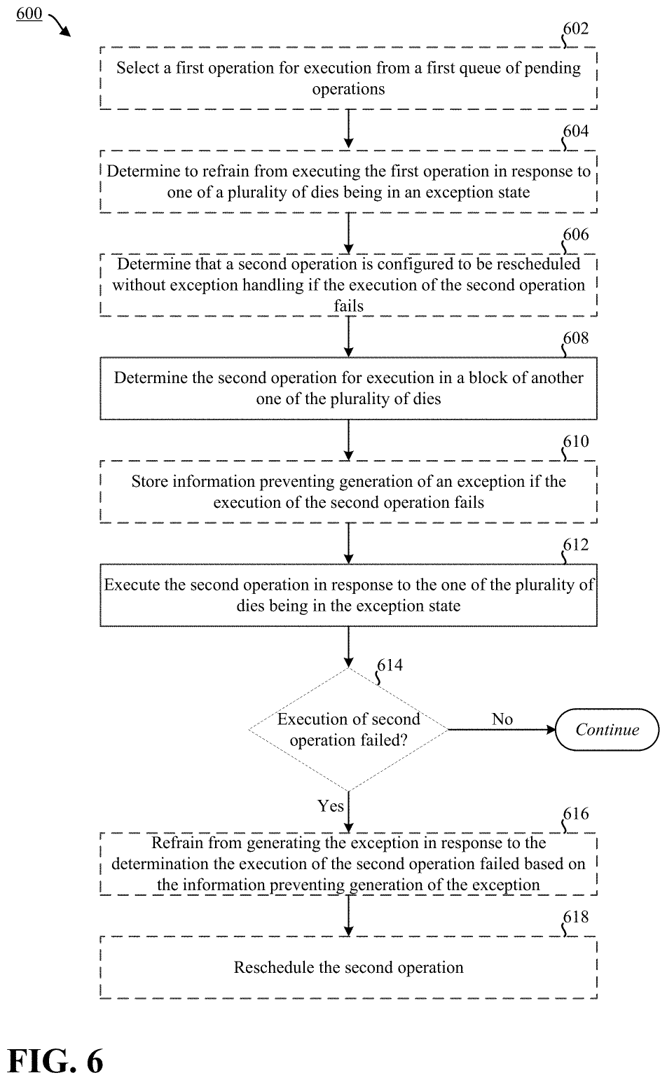

FIG. 6 illustrates an example flowchart 600 of a method for managing operations while EH is in progress. For example, the method may be performed in a storage device, such as the storage device 102 illustrated in FIG. 1. Each of the operations in the method can be controlled using a controller, a command dispatcher, or another processor as described below (e.g., the controller 123, the command dispatcher 302), or by some other suitable means.

As represented by block 602, the controller may select a first operation for execution from a first queue of pending operations. For example, referring to FIGS. 3-4, the command dispatcher 302 may select a 128 KB read 316a, read₀, for execution from the queues 304a-d of pending operations 316a-c.

As represented by block 604, the controller may determine to refrain from executing the first operation in response to one of a plurality dies being in an exception state. For example, referring to FIGS. 3-4, the command dispatcher 302 may determine to refrain from executing the 128 KB read 316a, read₀, in response to die₁ 310b being in the EH mode 320.

When the one of the plurality of dies is in the exception state, at least one of relocation of data stored in the one of the plurality of dies, an LDPC associated with the data, an XOR parity check associated with the data, or another ECC operation associated with the data may be performed.

In some embodiments, the first operation may be selected for execution in block(s) of the one of the plurality of dies in the exception state, and the determination to refrain from executing the first operation may then be based on the first operation being selected for execution in block(s) of the one of the plurality of dies in the exception state. In some other embodiments, the first operation is not configured to be rescheduled without EH if execution of the first operation fails, and the determination to refrain from executing the first operation may then be based on the first operation being not configured to be rescheduled without EH if the execution of the first operation fails.

As represented by block 606, the controller may determine that a second operation is configured to be rescheduled without EH if the execution of the second operation fails. For example, referring to FIGS. 3-4, the command dispatcher 302 may determine that a next 64 KB read 316b, read₁, is configured to be rescheduled without EH if the execution of read₁ fails.

The second operation may be determined for execution based on the determination to refrain from executing the first operation. According to various embodiments, the second operation may be one of a read operation, an internal memory operation, or another operation configured to be rescheduled without generating an exception if execution of the other operation fails. Potentially, the first operation may be in a first queue at a position that is earlier than a position of the second operation in a second queue; however, the controller may “skip” the first operation to determine the second operation for execution.

As represented by block 608, the controller may determine the second operation for execution in a block of another one of the plurality of dies. For example, referring to FIGS. 3-4, the command dispatcher 302 may determine the next 64B read 316b, read₁, for execution in blocks of die₂ 310c and die₃ 310d.

As represented by block 610, the controller may store information preventing generation of an exception if the execution of the second operation fails. For example, referring to FIGS. 3-4, the command dispatcher 302 may store information preventing generation of an exception if the execution of the next 64B read 316b, read₁, fails.

As represented by block 612, the controller may execute the second operation in response to the second die being in the exception state. For example, referring to FIGS. 3-4, the command dispatcher 302 may execute the next 64B read 316b, read₁, in response to die₁ 310b being in the EH mode 320.

As represented by block 614, the controller may determine whether execution of the second operation failed. For example, referring to FIGS. 3-4, the command dispatcher 302 may determine whether execution of the next 64B read 316b, read₁, failed.

If the controller determines that execution of the second operation did not fail (or determines that execution of the second operation was successful), then the controller may continue operation. For example, returning to block 602, the controller may select an operation for execution from a queue of pending operations. For example, referring to FIGS. 3-4, the command dispatcher 302 may determine the next 32B read 316c, read₃, for execution in block(s) of die₃ 310d.

If the controller determines that execution of the second operation did fail (or determines that execution of the second operation was unsuccessful), then as represented by block 616, the controller may refrain from generating the exception in response to the determination the execution of the second operation failed based on the information preventing generation of the exception. For example, referring to FIGS. 3-4, the command dispatcher 302 may refrain from generating any exceptions in response to determining that execution of the next 64B read 316b, read₁, failed.

As represented by block 618, the controller may then reschedule the second operation. For example, referring to FIGS. 3-4, the command dispatcher 302 may reschedule the next 64B read 316b, read₁, upon execution failure.

Accordingly, the present disclosure provides various embodiments of a storage device that is configured to execute some operations on one or more dies other than the die(s) in which EH is in progress. Such embodiments may improve upon approaches in which multiple dies (e.g., interleaved dies) are held in an idle state while EH is in progress on one die.

By executing some operations in blocks of dies in which EH is not occurring, latency in executing operations and responding to host requests may be reduced and/or other inefficiencies in management of operations may be mitigated during EH. Thus, the present disclosure describes various techniques and solutions that improve management of operations during EH.

The various aspects of this disclosure are provided to enable one of ordinary skill in the art to practice the present invention. Various modifications to exemplary embodiments presented throughout this disclosure will be readily apparent to those skilled in the art, and the concepts disclosed herein may be extended to other magnetic storage devices. Thus, the claims are not intended to be limited to the various aspects of this disclosure, but are to be accorded the full scope consistent with the language of the claims. All structural and functional equivalents to the various components of the exemplary embodiments described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112(f) in the United States, or an analogous statute or rule of law in another jurisdiction, unless the element is expressly recited using the phrase “means for” or, in the case of a method claim, the element is recited using the phrase “step for.”

What is claimed is:

1. A storage device, comprising:
a plurality of dies, each die including at least a block of memory; and
a controller configured to:
determine a first operation for execution in a first block of a first die of the plurality of dies, and
execute the first operation in response to a second die of the plurality of dies being in an exception state, the first die being different from the second die.

2. The storage device of claim 1, wherein the controller is further configured to:
determine that the first operation is configured to be rescheduled without exception handling if the execution of the first operation fails,
wherein the determination of the first operation is further based on the determination that the first operation is configured to be rescheduled without exception handling if the execution of the first operation fails.

3. The storage device of claim 2, wherein the controller is further configured to:
store information preventing generation of an exception if the execution of the first operation fails.

4. The storage device of claim 3, wherein the controller is further configured to:
determine the execution of the first operation failed;
refrain from generating the exception in response to the determination the execution of the first operation failed based on the information preventing generation of the exception; and
reschedule the first operation for another execution.

5. The storage device of claim 1, wherein the first operation comprises one of a read operation, an internal memory operation, or another operation configured to be rescheduled without generating an exception if execution of the other operation fails.

6. The storage device of claim 1, wherein the controller is further configured to:
select a second operation for execution from a first queue of pending operations;
determine to refrain from executing the second operation in response to the second die being in the exception state,
wherein the first operation is determined for the execution based on the determination to refrain from executing the second operation.

7. The storage device of claim 6, wherein the second operation is selected for execution in a second block of the second die, and the determination to refrain from executing the second operation is based on the second operation being selected for execution in the second block of the second die.

8. The storage device of claim 6, wherein the second operation is not configured to be rescheduled without exception handling if the execution of the second operation fails, and the determination to refrain from executing the second operation is based on the second operation being not configured to be rescheduled without exception handling if the execution of the second operation fails.

9. The storage device of claim 6, wherein the second operation is in the first queue at a position that is earlier than a position of the first operation in a second queue of pending operations.

10. The storage device of claim 1, wherein when the second die is in the exception state, at least one of relocation of data stored in the second die, a low-density parity-check (LDPC) associated with the data, an XOR parity check associated with the data, or another error correction code (ECC) operation associated with the data is performed.

11. A storage device, comprising:
a plurality of dies, each die including at least a block of memory; and
a controller configured to:
determine that a first die of the plurality of dies is configured in an exception handling (EH) mode;
select an operation to issue to a second die of the plurality of dies; and
perform the operation in a block of the second die when the first die is determined to be configured in the EH mode.

12. The storage device of claim 11, wherein the selection of the operation is based on the operation being configurable to be reissued without associated EH upon unsuccessful performance of the first operation and based on the operation corresponding to the second die.

13. The storage device of claim 12, wherein the operation is associated with metadata indicating associated EH is to be suppressed upon the unsuccessful performance of the first operation.

14. The storage device of claim 13, wherein the controller is further configured to:
suppress the associated EH based on the metadata in response to unsuccessful performance of the operation; and
reissue the operation when the first die is configured in the EH mode.

15. The storage device of claim 11, wherein the operation comprises at least one of a read request associated with a host device, an internally issued memory operation, or another operation configurable to be reissued without further EH upon failure of the other operation.

16. The storage device of claim 11, wherein the controller is further configured to:
refrain from selecting another operation in response to determination of at least one of:
the other operation as corresponding to the first die, or
the other operation as being configured for further EH upon failure of the other operation,
wherein the selection of the operation is based on the refraining from selecting the other operation.

17. A storage device, comprising:
a plurality of dies, each die including a block of memory; and
a controller configured to:
determine that an operation is configurable for execution without exception handling, and
execute the operation in the block of one die of the plurality of dies based on another die of the plurality of dies being in an exception state and based on the determination that the operation is configurable for execution without the exception handling.

18. The storage device of claim 17, wherein the controller is further configured to:
determine the operation is not scheduled for execution in the block of the other die,
wherein the execution of the first operation is further based on the determination that the operation is not scheduled for execution in the block of the other die.

19. The storage device of claim 17, wherein the controller is further configured to:
configure the operation for execution without the exception handling; and
refrain from the exception handling when the execution of the operation fails based on the configuration of the operation for execution without the exception handling.

20. The storage device of claim 17, wherein the operation comprises one of a read operation, an internal memory operation, or another operation configured to be rescheduled without generating an exception if execution of the other operation fails.
